(19) United States
(12) Patent Application Publication
(10) Pub. No.: US 2005/0179087 A1
(43) Pub. Date: Aug. 18, 2005

(54) LDMOS transistor with improved ESD protection

(76) Inventors: Geeng-Lih Lin, Hsinchu (TW); Yeh-Ning Jou, Taipei County (TW); Ming-Dou Ker, Hsinchu (TW)

Correspondence Address: BIRCH STEWART KOLASCH & BIRCH, PO BOX 747, FALLS CHURCH, VA, 22040-0747, US

(21) Appl. No.: 10/977,023

(22) Filed: Nov. 1, 2004

(30) Foreign Application Priority Data
Feb. 13, 2004 (TW) 093103468

(51) Int. Cl. H01L 23/62

(52) U.S. Cl. 257/356; 257/355; 257/360

(57) ABSTRACT

An ESD protection device. The ESD protection device is incorporated with a gap structure in a laterally diffused metal oxide semiconductor (LDMOS) field effect transistor, isolating a doped region and a field oxide region. When a parasitical semiconductor controlled rectifier (SCR) of LDMOS is turned off, ESD current is discharged distributively through several discharge paths, avoiding ESD current focus in a signal narrow discharge path and the danger therefrom.

### BACKGROUND OF THE INVENTION

1. Field of the Invention

The present invention relates to a protection device, and more particularly, to a high voltage electrostatic discharge (ESD) protection device.

2. Description of the Related Art

As the semiconductor manufacturing process develops, ESD protection has become one of the most critical reliability issues for integrated circuits (IC). In particular, as semiconductor process advances into the deep sub-micron stage, scaled-down devices and thinner gate oxides are more vulnerable to ESD stress. Generally, the input/output pads on IC chips must at least sustain 2 kVolt ESD stress of high Human Body Mode (HBM) or 200 V of Machine Mode. Thus, the input/output pads on IC chips usually include ESD protect devices or circuits protecting the core circuit from ESD damage.

FIG. 1 shows an ESD protection device as disclosed in U.S. Pat. No. 6,459,127. This Esb protection device is also a laterally diffused metal oxide semiconductor (LDMOS) field effect transistor. The LDMOS is N-type MOS with a gate 110 on a P substrate 100. An N+ region 112 acts as a source of the NMOS and an N well 102 a drain of the NMOS. An N+ region 106 is an electrical contact point of the well 102. The gate 110 controls the electrical connection of N+ region 112 and the N well 102 and is also coupled to a ground line VSS or a pre-driver according to circuit requirements.

The P substrate 100 is coupled to the grounded line VSS through the P+ region 116. The N+ region 112 is also coupled to the grounded line VSS. Through the N+ region 106, the drain is coupled to a pad. One parasitical SCR is composed with a P+ region 104, the N well 102, P substrate 100, and N+ region 112.

The parasitical SCR is turned on when positive ESD voltage is applied to the pad and the ground line VSS is grounded. Beginning at the pad, ESD current flows through the P+ region 104, N well 102, P substrate 100, and N+ region 112 and finally to the grounded line VSS to release ESD stress.

When ESD stress is not high enough to turn on the parasitical SCR, a secondary ESD current is discharged through the N+ region 106, N well 102, P substrate 100, and P+ region 116 to the grounded line VSS.

Since doped concentration of the N+ region 106 is higher, the impedance of the N+ region 106 is lower. On the contrary, the doped concentration of the N well 102 is lower such that the impedance of the N well 102 is higher. Most of the secondary ESD current discharges through a discharge path having minimum impedance. In FIG. 1, discharge path A has minimum impedance between the N+ region 106 and the N well 102. Thus, the secondary ESD current is released along the discharge path A to the grounded line VSS when the parasitical SCR is still turned off.

In the discharge path A, the secondary ESD current, reaching a field oxide region 108, changes direction. Since the secondary ESD current stays large, the change in direction generates a higher temperature in the turning point, easily damaging the field oxide region 108 and the discharge path.

### SUMMARY OF THE INVENTION

It is therefore an object of the present invention to provide an electrostatic discharge (ESD) protection device to avoiding excess current focus along a signal discharge path.

The ESD protection device according to the present invention comprises a first substrate of a first conductive type, a well of a second conductive type, a first doped region of the second conductive type, a gate, a second doped region of the third conductive type, a field oxide region, and a gap. The well and the first doped region are formed in the substrate. The gate controls the electrical connection of the first doped region and the well. A field effect transistor comprises the gate, the first doped region, and the well. The second doped region, field oxide region, and gap are formed in the well. The field oxide region is located between the gate and the second doped region. The gap is located between the field oxide region and the second doped region. The first and the third conductivity types can be either N or P type. The second conductivity type can be either P or N type.

### BRIEF DESCRIPTION OF THE DRAWINGS

The present invention can be more fully understood by reading the subsequent detailed description and examples with reference made to the accompanying drawings, wherein:

FIG. 1 shows an ESD protection device as disclosed in U.S. Pat. No. 6,459,127;

FIG. 2 is a cross-section of an ESD protection device according to a first embodiment of the present invention;

FIG. 3 is a cross-section of another ESD protection device according to the present invention;

FIG. 4 is a cross-section of another ESD protection device according to the present invention;

FIG. 5 is a cross-section of another ESD protection device according to the present invention.

### DETAILED DESCRIPTION OF THE INVENTION

FIG. 2 is a cross-section of an ESD protection device according to a first embodiment of the present invention. The ESD protection device is an N-type LDMOS field effect transistor. The NMOS comprises gate 210, N+ region 212, and N well 202. N+ region 212 is a source of the NMOS and N well 202 a drain of the NMOS. An N+ region 206 formed in the N well 202 acts as an electrical contact for the N well 202. The gate 210 controls the electrical connection of N+ region 212 and the N well 202, and is also coupled to a grounded line VSS or pre-driver according to circuit requirements.

The P substrate 200 is coupled to the grounded line VSS through a P+ region 216. The drain is coupled to a pad through the N+ region 206.

A field oxide region 214 isolates the N+ region 212 from P+ region 216. In order to protect a gate-oxide layer under the gate 210 from overstress, a field oxide region 208 is formed between an N+ region 206 and gate 210 isolating the gate 210 from N well 202. The field oxide region 208 and 214 are formed by shallow trench isolation (STI) or local oxidation of silicon (LOCOS). A gap separates field oxide region 208 and the N+ region 206.

The P+ region 204 is formed in the N well 202 and coupled to pad. The P+ region 204 can be located between the gap and the N+ region 206, or the N+ region 206 can be located between the gap and the P+ region 204. Since the P+ region 204 is formed, a parasitical SCR is also formed. The P+ region 204, N well 202, P substrate 200, and N+ region 212 all constitute the parasitical SCR.

A pn junction is formed between the P substrate 200 and the N well 202. The P substrate 200 is coupled to the grounded line VSS through the P+ region 216 and the N well 202 is coupled to the pad through the N+ region 206. When negative ESD voltage is applied to the pad and the grounded line VSS is grounded, the PN junction between the P substrate 200 and the N well 202 is forward biased and the pad and the grounded line VSS act as equivalent shorts, allowing release of ESD stress.

When positive ESD voltage is applied to the pad and the grounded line VSS is grounded, the parasitical SCR is turned on. ESD current flows through the pad, P+ region 204, N well 202, P substrate 200, N+ region 212, and finally to the grounded line VSS.

When ESD occurs in the pad but is insufficient to turn on the parasitical SCR, a secondary ESD current is discharged through the N+ region 206, the N well 202, the P substrate 200, and the P+ region 216 to the grounded line VSS as discharge paths B and C.

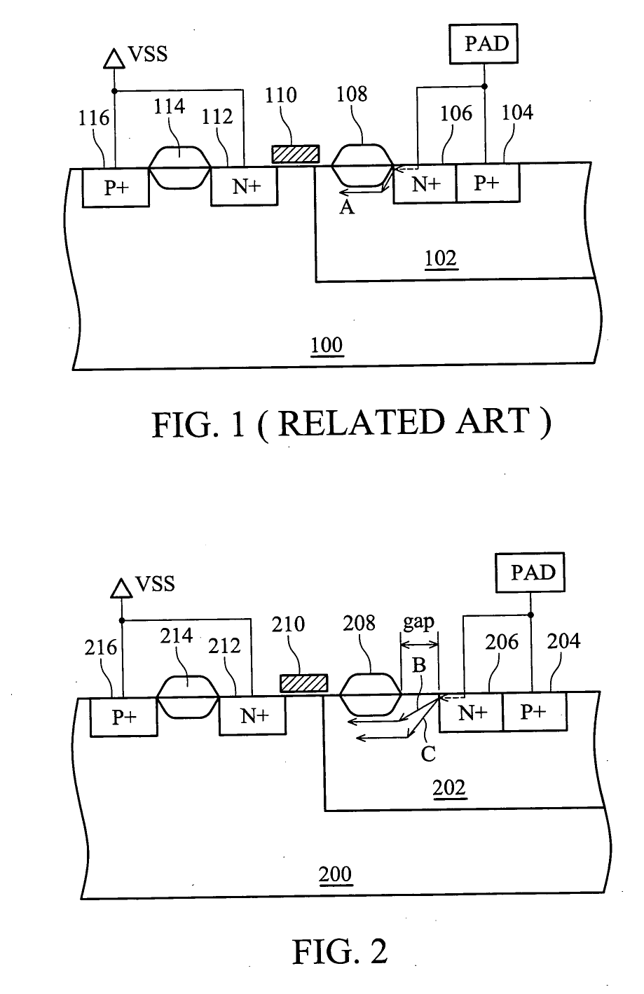

Since the gap is located between the field oxide region 208 and the N+ region 206, the secondary ESD current does not contact the field oxide region 208. If all region sizes are the same in FIGS. 1 and 2, in FIG. 1, the secondary ESD current is focused at discharge path A such that the field oxide region 108 is easily damaged, and in FIG. 2, the ESD protection device of the present invention disperses the secondary ESD current to the grounded line VSS through multiple discharge paths B and C.

The gap is defined by mask pattern. After the field oxide region 208 is formed, the N+ region 206 is formed by a mask pattern, defining the N+ region separated from the field oxide region 208. If the gap is doped with positive P+, a high impedance region between the field oxide region 208 and the N+ region 206 further avoids secondary ESD current contact with the field oxide region 208.

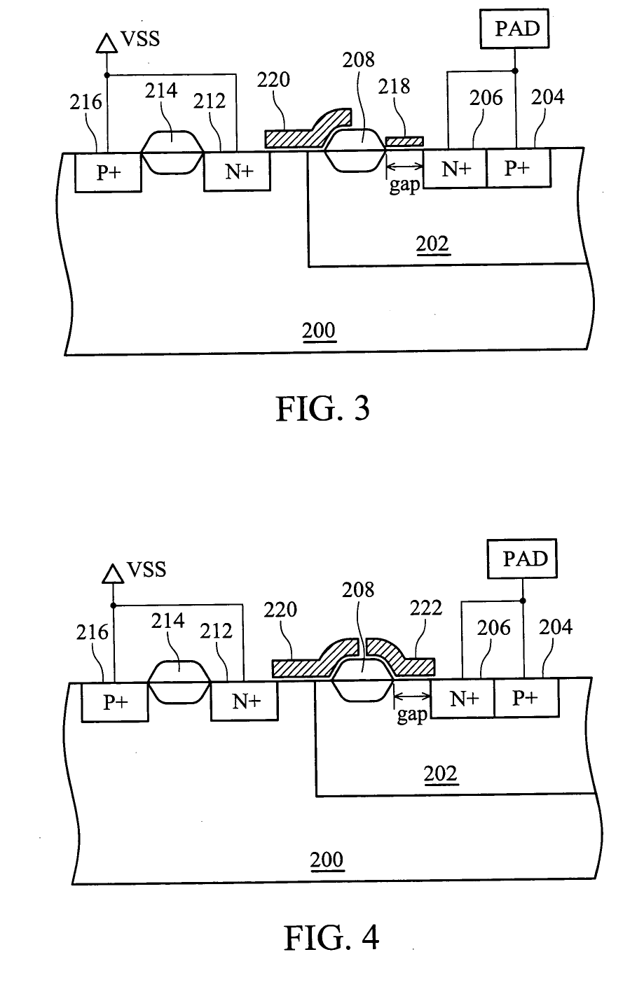

FIG. 3 is a cross-section of another ESD protection device according to the present invention. The same elements utilize the same symbols as in FIGS. 2 and 3. A dummy gate 218 is formed by a mask pattern and located between the field oxide region 208 and the N+ region 206. The dummy gate 218 may be a floating gate uncoupled to any direct current signal. The gate 220 is located between the field oxide region 208 and the N+ region 212, and part of the gate 220 extends to cover the field oxide region 208.

FIG. 4 is a cross-section of another ESD protection device according to the present invention. A dummy gate 222 is formed between the gate 220 and the N+ region 206 and part of the dummy gate 222 covers the field oxide region 208.

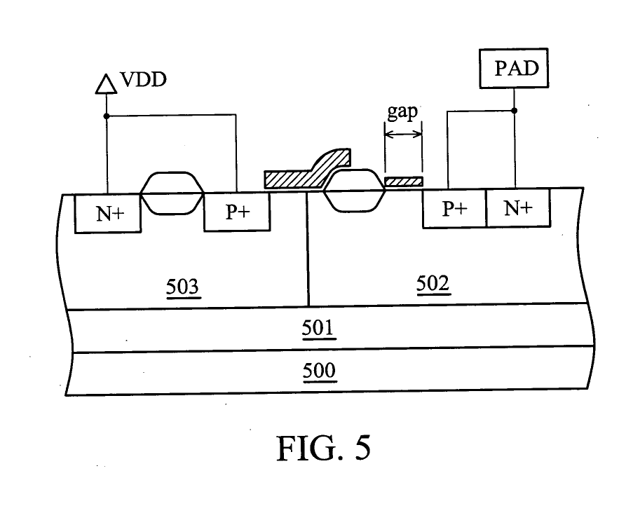

FIG. 5 is a cross-section of another ESD protection device according to the present invention. The ESD protection device is a P-type LDMOS. An N-type buried layer 501 is formed in a P substrate 500. The N-type buried layer 501 and an N well 503 are as an N substrate of the P-type LDMOS. The grounded line VSS in FIG. 3 is a power line VDD in FIG. 5 and N-type and P-type doping regions are reversed.

Additionally, N-type and P-type elements are formed on P substrate shown in FIGS. 3 and 5. Nonetheless, the present invention can be also applied with N-type or P-type elements formed on P substrate. Conversion between P-type and N-type components is well known to those skilled in the field and therefore is not discussed.

Since, according to the present invention, a gap exists between a field oxide region and an N+ region, secondary ESD current occurring at the outset of an ESD event before activation of a parasitic SCR, is not focused along a single discharge path, such that danger of burnout along the path is avoided.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

1. An electrostatic discharge (ESD) protection device, comprising:
a first substrate of a first conductive type;
a well of a second conductive type in the substrate;
a first doped region of the second conductive type in the substrate;
a gate controlling the electrical connection of the first doped region and the well, wherein a field effect transistor comprises the gate, the first doped region, and the well;
a second doped region of the third conductive type in the well;
a field oxide region in the well and between the gate and the second doped region; and
a gap in the well and between the field oxide region and the second doped region.

2. The ESD protection device as claimed in claim 1, further comprising a third doped region of the first conductive type in the substrate acting as a contact point thereof.

3. The ESD protection device as claimed in claim 2, wherein the first and the third conductive types are P-type and the second conductive type N-type.

4. The ESD protection device as claimed in claim 1, wherein the first conductive type is P-type and the second and the third conductive types N-type.

5. The ESD protection device as claimed in claim 4, wherein the first and the third doped regions are connected to a first power line when the ESD protection device operates normally.

6. The ESD protection device as claimed in claim 2, wherein the first and the third conductive types are N-types and the second conductive type is P-type.

7. The ESD protection device as claimed in claim 2, wherein the first conductive type is N-type and the second and the third conductive types are P-types.

8. The ESD protection device as claimed in claim 7, wherein the first and the third doped regions are connected to a second power line when the ESD protection device operates normally.

9. The ESD protection device as claimed in claim 1, wherein the field oxide region is formed by shallow trench isolation (STI) or local oxidation of silicon (LOCOS).

10. The ESD protection device as claimed in claim 1, wherein the gap is defined by a mask.

11. The ESD protection device as claimed in claim 1, further comprising a dummy gate between the second doped region and the field oxide region.
